(19) United States
(12) Patent Application Publication
(10) Pub. No.: US 2010/0314765 A1
(43) Pub. Date: Dec. 16, 2010

(54) INTERCONNECTION STRUCTURE OF SEMICONDUCTOR INTEGRATED CIRCUIT AND METHOD FOR MAKING THE SAME

(76) Inventors: Wen-Ping Liang, Taipei County (TW); Yu-Shan Chiu, Taipei County (TW); Kuo-Hui Su, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/485,909

(22) Filed: Jun. 16, 2009

(51) Int. Cl. H01L 23/522; H01L 23/532; H01L 21/768

(52) U.S. Cl. 257/751; 257/758; 438/627; 257/E23.145; 257/E23.158; 257/E23.161; 257/E21.584

(57) ABSTRACT

An interconnection structure includes a lower layer metal wire in a first inter-metal dielectric layer on a substrate; a second inter-metal dielectric layer on the first inter-metal dielectric layer and covering the lower layer metal wire; an upper layer metal wire on the second inter-metal dielectric layer; and a via interconnection structure in the second inter-metal dielectric layer for interconnecting the upper layer metal wire with the lower layer metal wire, wherein the via interconnection structure comprises a tungsten stud on the lower layer metal wire, and an aluminum plug stacked on the tungsten stud.

### BACKGROUND OF THE INVENTION

1. Field of the Invention

The present invention relates generally to semiconductor technology and, more particularly, to a metal interconnection structure involving a low-resistance via structure for interconnecting a lower layer copper wire (e.g. metal-2 or M2) with an upper layer aluminum wire (e.g. metal-3 or M3), and to a method for making the same.

2. Description of the Prior Art

High conductivity of interconnection of an integrated circuit is important for the efficient operation of such a circuit, particularly at submicron technologies. In previous integrated circuits, aluminum has been utilized to provide interconnect for the device. However, as standards for speed have increased, i.e., smaller and smaller process technologies (0.18 μm and lower), other metals have been used. In a preferred embodiment, high conductivity metals such as copper have been used as the interconnection to enhance the speed of the device.

Copper-based chips are semiconductor integrated circuits, which use copper for interconnections. Since copper is a better conductor than aluminum, chips using this technology can have smaller metal components, and use less energy to pass electricity through them. Together, these effects lead to higher-performance chips. The transition from aluminum to copper required significant developments in fabrication techniques including radically different methods for patterning the metal as well as the introduction of barrier metal layers to isolate the silicon from potentially damaging copper atoms.

Because of the lack of volatile copper compounds, copper could not be patterned by the previous techniques of photoresist masking and plasma etching that had been used with great success with aluminum. The inability to plasma etch copper called for a drastic rethinking of the metal patterning process and the result of this rethinking was a process referred to as a copper damascene process.

In this process, the underlying silicon oxide insulating layer is patterned with open trenches where the conductor should be. A thick coating of copper that significantly overfills the trenches is deposited on the insulator, and chemical-mechanical polishing (CMP) is used to remove the copper outside the trench. Copper embedded within the trenches of the insulating layer is not removed and becomes the patterned conductor. Since diffusion of copper into surrounding materials would degrade the reliability of the integrated circuit chip, a barrier metal layer is provided to encapsulate the damascened copper interconnections. A barrier metal must limit copper diffusivity sufficiently to chemically isolate the copper conductor from the silicon below, yet have high electrical conductivity in order to maintain a good electronic contact.

The thickness of the barrier film is also quite important; with too thin a layer, the copper contacts poison the very devices that they connect to; with too thick a layer, the stack of two barrier metal films and a copper conductor have a greater total resistance than an aluminum interconnection would have, eliminating that benefit of the technology.

FIGS. 1-4 are schematic, cross-sectional diagrams showing a prior art method for fabricating a via interconnection structure of an integrated circuit. As shown in FIG. 1, a lower layer copper wire 14 that is encapsulated by a barrier film 15 and a capping layer 16 is provided in an inter-metal dielectric layer 12 that is typically deposited on a semiconductor substrate 10 such as a silicon substrate. An inter-metal dielectric layer 18 is deposited on the capping layer 16 by methods known in the art, for example, chemical vapor deposition (CVD) methods.

Subsequently, as shown in FIG. 2, a via hole 18a is formed in the inter-metal dielectric layer 18 and the capping layer 16 to expose a portion of the top surface of the lower layer copper wire 14. Meanwhile, polymer residuals 19 that are formed during the etching of the via hole 18a are ordinarily found in the via hole 18a.

As shown in FIG. 3, in order to remove the polymer residuals 19 from the via hole 18a, a wet etching or wet cleaning process is carried out. However, this wet etching or wet cleaning process leads to a serious via undercut problem as indicated by numeral number 18b. It has been experimentally found that copper may diffuse out by way of the via undercut defect point and eventually reacts with the upper layer aluminum wire, thereby degrading the performance and reliability of the integrated circuits.

As shown in FIG. 4, a barrier film 20 typically including a layer of titanium nitride 22 and a layer of titanium 24 is deposited by physical vapor deposition (PVD) processes. An upper layer aluminum wire 26 is then provided on the barrier film 20 and fills into the via hole 18a. To remedy the aforesaid via undercut problem and potential copper diffusion, the bottom and corner step coverage of the subsequent barrier film 20 must be improved by tuning the parameters during the PVD process.

Nevertheless, the increase of the bottom and corner step coverage of the barrier film 20, on the other hand, causes via top overhang problem as indicated by numeral number 25 of FIG. 4 at the inlet of the via hole 18a. The via top overhang may hinder the aluminum from successfully filling into the via hole 18a and may cause gap in the via hole and failure of interconnection between the lower layer copper wire 14 and the upper layer aluminum wire 26.

In light of the above, there is a strong need in this industry to provide an improved interconnection structure involving a low-resistance via for interconnecting a lower layer copper wire with an upper layer aluminum wire, and a method for making the same, which are capable of avoiding the aforesaid problems.

### SUMMARY OF THE INVENTION

It is one object of the invention to provide an improved metal interconnection structure involving a low-resistance via structure for interconnecting a lower layer copper wire with an upper layer aluminum wire, which is capable of preventing the prior art problems.

It is another object of the invention to provide an improved method of making such metal interconnection structure, which is compatible with current process flow and is cost-effective.

According to one preferred embodiment of this invention, an interconnection structure of an integrated circuit includes a substrate; a lower layer metal wire in a first inter-metal dielectric layer on the substrate; a second inter-metal dielectric layer on the first inter-metal dielectric layer and covering the lower layer metal wire; an upper layer metal wire on the second inter-metal dielectric layer; and a via interconnection structure in the second inter-metal dielectric layer for interconnecting the upper layer metal wire with the lower layer metal wire, wherein the via interconnection structure comprises a tungsten stud on the lower layer metal wire, and an aluminum plug stacked on the tungsten stud.

In one aspect, in accordance with another embodiment of this invention, a method of fabricating an interconnection structure of an integrated circuit includes providing a substrate having thereon a first inter-metal dielectric layer; forming a lower layer metal wire in the first inter-metal dielectric layer; forming a second inter-metal dielectric layer on the first inter-metal dielectric layer; forming a via hole in the second inter-metal dielectric layer to expose a top surface of the lower layer metal wire; forming a tungsten stud at a bottom of the via hole; forming a metal layer on the second inter-metal dielectric layer to fill the via hole; and patterning the metal layer into an upper layer metal wire.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 are schematic, cross-sectional diagrams showing a prior art method for fabricating a via interconnection structure of an integrated circuit.

FIGS. 5-10 are schematic, cross-sectional diagrams showing a method for fabricating a via interconnection structure of an integrated circuit in accordance with one preferred embodiment of this invention.

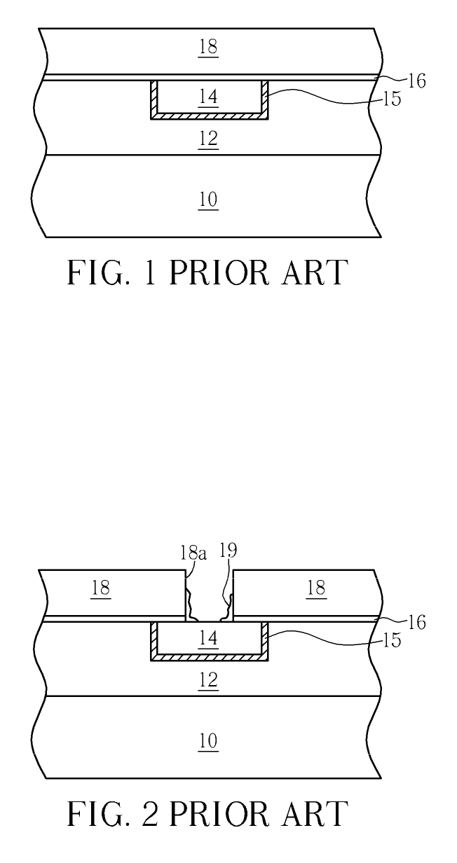

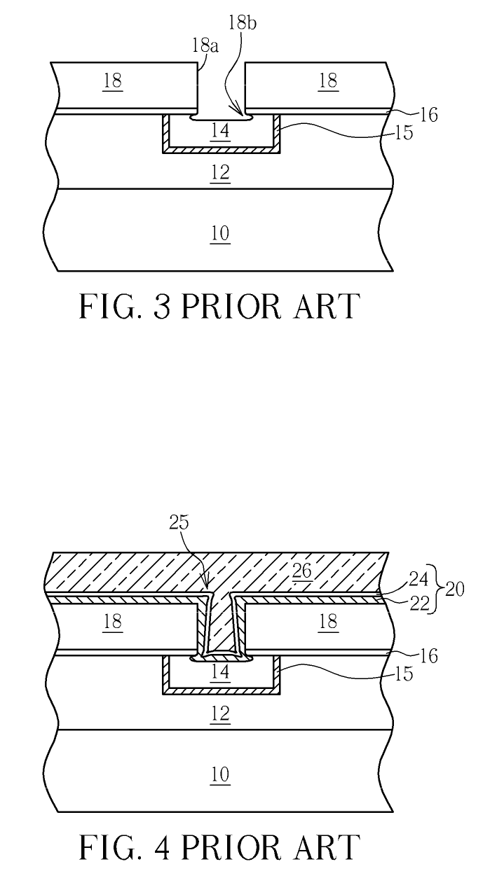

### DETAILED DESCRIPTION

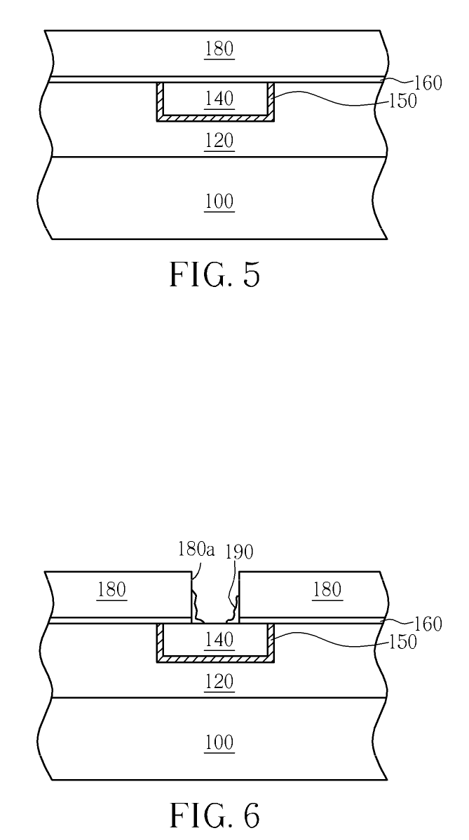

FIGS. 5-10 are schematic, cross-sectional diagrams showing a method for fabricating a via interconnection structure of an integrated circuit in accordance with one preferred embodiment of this invention. As shown in FIG. 5, a semiconductor substrate 100 such as a silicon substrate is provided. An inter-metal dielectric layer 120 such as silicon oxide or low-k dielectric is deposited on the semiconductor substrate 10. A lower layer copper wire 140 is inlaid in the inter-metal dielectric layer 120 using methods known in the art, for example, copper damascene processes. Likewise, the lower layer copper wire 140 is encapsulated by a barrier film 150 and a capping layer 160. The barrier film 150 may comprise titanium, titanium, tantalum or tantalum nitride. The capping layer 160 may comprise silicon nitride, silicon carbide, silicon oxide or the like. It is understood that in some cases, the capping layer 160 may be omitted. An inter-metal dielectric layer 180 such as silicon oxide or low-k dielectric is then deposited on the capping layer 160 by methods known in the art, for example, chemical vapor deposition (CVD) methods. For example, the lower layer copper wire 140 may be of the metal-2 or M2 level of the interconnection scheme of the integrated circuit.

As shown in FIG. 6, a via hole 180a is formed in the inter-metal dielectric layer 180 and the capping layer 160 to expose a portion of the top surface of the lower layer copper wire 140. Meanwhile, polymer residuals 190 that are formed during the etching of the via hole 180a may be found in the via hole 180a. The formation of the via hole 180a may include lithographic and etching steps known in the art, for example, coating of photoresist, exposure of the photoresist, developing and patterning of the coated photoresist, and anisotropic dry etching of the inter-metal dielectric layer 180 and the capping layer 160 that is not covered by the patterned photoresist (not shown).

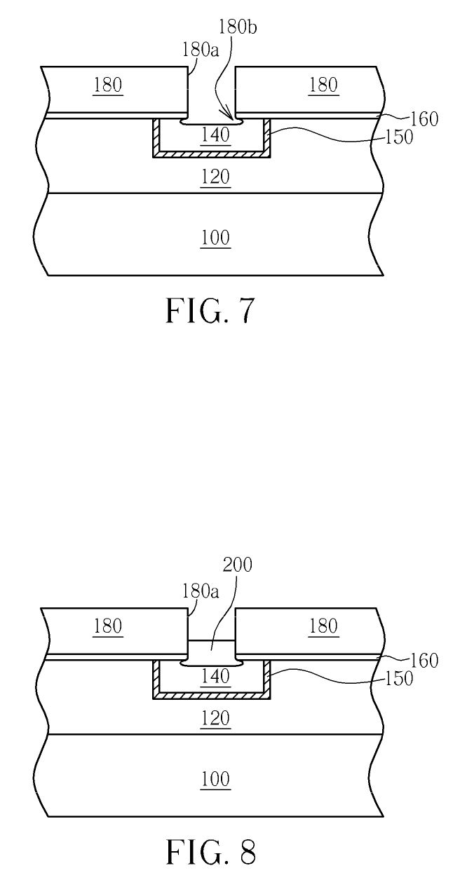

As shown in FIG. 7, in order to remove the polymer residuals 190 from the via hole 180a, a wet etching or wet cleaning process is carried out. Inevitably, this wet etching or wet cleaning process leads to a via recess undercut 180b. It has been experimentally found that copper may diffuse out by way of the via recess undercut 180b and eventually reacts with the upper layer aluminum wire, thereby degrading the performance and reliability of the integrated circuits. This invention addresses this issue.

As shown in FIG. 8, after the wet etching or wet cleaning process for removing the polymer residuals 190, in accordance with the preferred embodiment, a reductive hydrogen plasma treatment may be carried out. The reductive hydrogen plasma treatment may be used to reduce copper oxide inside the via hole 180a to copper metal. However, it is understood that the reduction of the copper oxide may be implemented by non-plasma methods such as using other non-plasma reducing agents.

After the reduction of the exposed top surface of the lower layer copper wire 140, a selective tungsten deposition process is immediately performed to selectively deposit a tungsten stud 200 at the bottom of the via hole 180a. The aforesaid selective tungsten deposition process may comprise selective tungsten chemical vapor deposition (CVD) processes or selective tungsten atomic layer deposition (ALD) processes.

In a preferred embodiment, for example, a selective tungsten ALD process may comprise a plurality of ALD cycles and each of the ALD cycles may further include the following sub-steps: (1) flowing hydrogen-containing substance such as silane or hydrogen gas into a chamber for a period of time to adsorb hydrogen radicals on the surface of the inter-metal dielectric layer 180 and on the lower layer copper wire 140; (2) pumping down the chamber while stopping all gas flow to selectively remove the hydrogen radicals merely from the surface of the inter-metal dielectric layer 180; (3) flowing tungsten precursor such as tungsten hexafluoride (WF₆) into the chamber at a low pressure (below 5 torr) and low temperature (below 300° C.) to react with the remanent hydrogen radicals adsorbed merely on the lower layer copper wire 140, thereby selectively depositing a tungsten atomic layer thereto; and (4) purging the chamber with inert gas such as argon to remove by-products. It is understood that the desired thickness of the tungsten stud 200 can be achieved by repeating the ALD cycle.

In accordance with the preferred embodiment of this invention, the tungsten stud 200 inside the via hole 180a has a thickness ranging between 100 angstroms and 400 angstroms. In addition, the top surface of the tungsten stud 200 is lower than the top surface of the inter-metal dielectric layer 180. According to the preferred embodiment, the tungsten stud 200 fills into and engages with the via recess undercut 180b, thereby forming good contact interface between the tungsten stud 200 and the lower layer copper wire 140.

Since the tungsten stud 200 has lower resistivity than that of the PVD TiN or PVD TaN, the speed or performance of the integrated circuit can be improved. Further, by choosing the selective tungsten deposition method, a conventional PVD TiN or PVD TaN process can be skipped, thereby avoiding the overhang that typically occurs at the inlet of the via hole and enhancing the yield of the subsequent aluminum filling step.

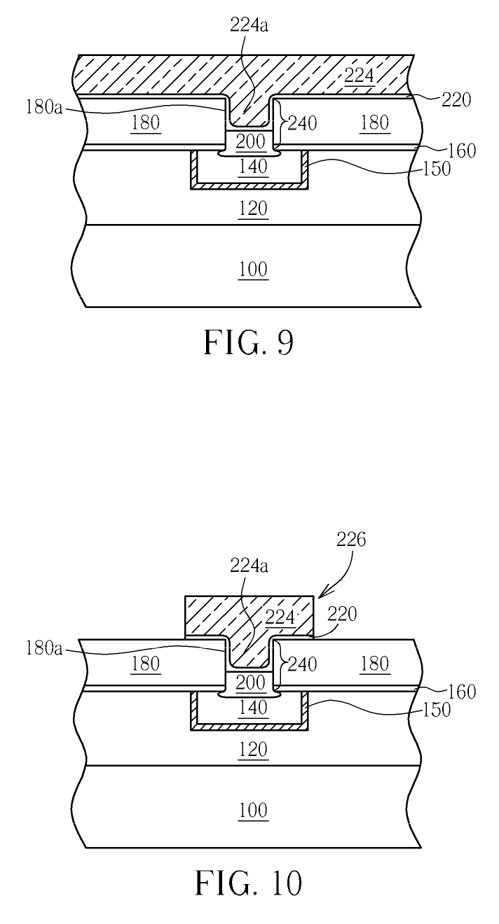

As shown in FIG. 9, after the formation of the tungsten stud 200 inside the via hole 180a, optionally, a conformal wetting metal layer 220 such as a thin layer of titanium or tantalum is deposited onto the top surface of the tungsten stud 200, the sidewall of the via hole 180a and on the top surface of the inter-metal dielectric layer 180. Preferably, the wetting metal layer 220 has a thickness ranging between 100 angstroms and 400 angstroms. The wetting metal layer 220 may be formed by CVD, ALD, PVD or any suitable methods known in the art. Subsequently, an aluminum layer 224 is deposited onto the wetting metal layer 220 and fills into the via hole 180a, thereby forming an integral aluminum plug 224a at an upper portion of the via hole 180a. The aluminum layer 224 may be formed by CVD, PVD, sputtering or any suitable methods known in the art.

At this point, an improved via interconnection structure 240 is completed. In this embodiment, the via interconnection structure 240 comprises the tungsten stud 200 inlaid at the bottom of the via hole 180a, a wetting meta layer 220 lining the tungsten stud 200 and the sidewall of the via hole 180a, and the aluminum plug 224a that is formed integrally with the overlying aluminum layer 224. The resultant via interconnection structure 240 is analogous to a reversed flat-head thumbtack.

As shown in FIG. 10, the aluminum layer 224 and the wetting metal layer 220 are patterned into an upper layer aluminum wire 226. The upper layer aluminum wire 226 is electrically interconnected with the lower layer copper wire 140 through the improved via interconnection structure 240. The definition and patterning of the upper layer aluminum wire 226 may involve conventional lithographic and etching steps that are well known in the art, for example, coating of photoresist, exposure of the photoresist, developing and patterning of the coated photoresist, and anisotropic dry etching of the that is not covered by the patterned photoresist (not shown).

In sum, the advantages of using this invention at least include: (1) the via/contact resistance can be reduced because the tungsten stud 200 has lower resistivity than that of the PVD TiN or PVD TaN that is conventionally used as copper diffusion barrier in the via hole; (2) the overhang issue of the prior art method can be effectively solved because the PVD TiN or TaN deposition process is omitted; and (3) the via recess undercut defect can be mended by the selective tungsten deposition process, thereby effectively blocking the potential diffusion path of the copper atoms. Both of the yield of manufacture and reliability of the integrated circuit can be significantly improved.

Those skilled in the art will readily observe that numerous modifications and alterations of the device and method may be made while retaining the teachings of the invention.

What is claimed is:

1. An interconnection structure of an integrated circuit, comprising:
a substrate;
a lower layer metal wire in a first inter-metal dielectric layer on the substrate;
a second inter-metal dielectric layer on the first inter-metal dielectric layer and covering the lower layer metal wire;
an upper layer metal wire on the second inter-metal dielectric layer; and
a via interconnection structure in the second inter-metal dielectric layer for interconnecting the upper layer metal wire with the lower layer metal wire, wherein the via interconnection structure comprises a tungsten stud on the lower layer metal wire, and an aluminum plug stacked on the tungsten stud.

2. The interconnection structure of an integrated circuit according to claim 1 wherein the upper layer metal wire is an aluminum wire.

3. The interconnection structure of an integrated circuit according to claim 2 wherein the aluminum plug is formed integrally with the upper layer metal wire.

4. The interconnection structure of an integrated circuit according to claim 1 wherein the lower layer metal wire is a copper wire inlaid in the first inter-metal dielectric layer.

5. The interconnection structure of an integrated circuit according to claim 4 wherein the lower layer metal wire is encapsulated by a barrier film and a capping layer.

6. The interconnection structure of an integrated circuit according to claim 5 wherein the barrier film comprises titanium, titanium, tantalum, or tantalum nitride.

7. The interconnection structure of an integrated circuit according to claim 5 wherein the capping layer comprise silicon nitride, silicon carbide, or silicon oxide.

8. The interconnection structure of an integrated circuit according to claim 5 wherein the capping layer is interposed between the first inter-metal dielectric layer and second inter-metal dielectric layer.

9. The interconnection structure of an integrated circuit according to claim 1 further comprising a wetting metal layer interposed between the tungsten stud and the aluminum plug.

10. The interconnection structure of an integrated circuit according to claim 9 wherein the wetting meta layer comprises titanium or tantalum.

11. The interconnection structure of an integrated circuit according to claim 1 wherein the via interconnection structure is inlaid in a via hole with a via recess undercut.

12. The interconnection structure of an integrated circuit according to claim 11 wherein the tungsten stud fills into and engages with the via recess undercut.

13. A method of fabricating an interconnection structure of an integrated circuit, comprising:
providing a substrate having thereon a first inter-metal dielectric layer;
forming a lower layer metal wire in the first inter-metal dielectric layer;
forming a second inter-metal dielectric layer on the first inter-metal dielectric layer;
forming a via hole in the second inter-metal dielectric layer to expose a top surface of the lower layer metal wire;
forming a tungsten stud at a bottom of the via hole;
forming a metal layer on the second inter-metal dielectric layer to fill the via hole; and
patterning the metal layer into an upper layer metal wire.

14. The method according to claim 13 wherein the metal layer is an aluminum layer.

15. The method according to claim 13 wherein the lower layer metal wire is a copper wire inlaid in the first inter-metal dielectric layer.

16. The method according to claim 15 wherein the lower layer metal wire is encapsulated by a barrier film and a capping layer.

17. The method according to claim 16 wherein the barrier film comprises titanium, titanium, tantalum, or tantalum nitride.

18. The method according to claim 16 wherein the capping layer comprise silicon nitride, silicon carbide, or silicon oxide.

19. The method according to claim 13 further comprising:
lining a top surface of the tungsten stud, sidewalls of the via hole and a top surface of the second inter-metal dielectric layer with a wetting metal layer.

20. The method according to claim 19 wherein the wetting meta layer comprises titanium or tantalum.

21. The method according to claim 13 wherein after forming the via hole and before forming a tungsten stud, the method further comprises:
performing a wet cleaning process to remove polymer residuals inside the via hole; and
performing a reductive hydrogen plasma treatment to reduce copper oxide inside the via hole to copper metal.

22. The method according to claim 13 wherein the tungsten stud partially fills the via hole and has a top surface lower than that of the second inter-metal dielectric layer.

23. The method according to claim 13 wherein the tungsten stud is formed by a selective tungsten deposition method.
